(19) United States
(12) Patent Application Publication
(10) Pub. No.: US 2011/0291691 A1
(43) Pub. Date: Dec. 1, 2011

(54) CHIP AND CHIP TEST SYSTEM

(75) Inventor: Sunghoon Cho, Yongin-si (KR)

(73) Assignee: SAMSUNG ELECTRONICS CO., LTD., Suwon-si (KR)

(21) Appl. No.: 13/097,477

(22) Filed: Apr. 29, 2011

(30) Foreign Application Priority Data
Jun. 1, 2010 (KR) 10-2010-0051887

(51) Int. Cl. G01R 31/02; G05F 3/02; H03K 3/01

(52) U.S. Cl. 324/762.01; 327/534; 327/545

(57) ABSTRACT

According to an example embodiment, a chip includes a plurality of circuit blocks, a power switch unit configured to supply power to the plurality of circuit blocks, and a power switch controller configured to control the power switch unit in response to an external control signal. The external control signal selectively control supply of power to at least one circuit block of the plurality of circuit blocks.

### CROSS-REFERENCE TO RELATED APPLICATIONS

This application claims priority under 35 U.S.C. §119 to Korean Patent Application No. 10-2010-0051887 filed Jun. 1, 2010 in the Korean Intellectual Property Office (KIPO), the contents of which are incorporated herein by reference in their entirety.

### BACKGROUND

Example embodiments relate to a chip test system.

With the development of highly integrated semiconductor technology, various functions of a chip are converged. An application area of a chip (e.g., System on Chip (SoC)) gradually expands into mobile communication and information home appliances in addition to a personal computer. Currently, various functions are gradually converged into a SoC.

Thus, as the SoC becomes highly integrated, its test function becomes more important and as an application area of a product becomes diversified, quality assurance about product operation is required. For this, the SoC is tested during manufacturing processes.

A test device is used to test the SoC. The test device may perform various tests (current test, temperature test, high voltage stress test (HVS), function operation test, speed test, and so forth) on a corresponding SoC. The test device determines whether a test value detected from a test chip is within an allowable error range. Through this, the test device determines whether the corresponding chip is defective or not.

### SUMMARY

According to example embodiments of the inventive concepts, a chip includes a plurality of circuit blocks, a power switch unit configured to supply power to the plurality of circuit blocks, and a power switch controller configured to control the power switch unit in response to an external control signal, the external control signal selectively controlling supply of power to at least one circuit block of the plurality of circuit blocks.

According to example embodiments of the inventive concepts, the power switch unit controls the supply of power to each of the plurality of circuit blocks and includes a plurality of switches configured to control the supply of power to the plurality of circuit blocks.

According to example embodiments of the inventive concepts, the external control signal includes a plurality of external switch control signals configured to control each of the plurality of switches.

According to example embodiments of the inventive concepts, the chip further includes a floating prevention controller configured to prevent leakage current caused by an input pin.

According to example embodiments of the inventive concepts, the floating prevention controller includes a flip flop configured to receive a data signal, and a multiplexer connected to the input pin and the flip flop, and configured to provide the data signal to a core of the chip to prevent the leakage current.

According to example embodiments of the inventive concepts, the input pin includes an input/output pin set to have an input function.

According to example embodiments of the inventive concepts, a chip test system includes a test device, and a chip tested by the test device. The chip includes a plurality of circuit blocks, a power switch unit configured to supply power to the plurality of circuit blocks, and a power switch controller configured to control the power switch unit in response to an external control signal. The external control signal selectively controls supply of power to at least one circuit block of the plurality of circuit blocks.

According to example embodiments of the inventive concepts, the test device includes a power supply unit configured to supply power to the chip, and a current measuring unit configured to measure a standby current flowing in the chip while supply of power to the plurality of circuit blocks in the chip is being controlled in response to the external control signal.

According to example embodiments of the inventive concepts, the current measuring unit measures the standby current using the power supplied to the chip.

According to example embodiments of the inventive concepts, the power switch unit controls the supply of power to each of the plurality of circuit blocks and includes a plurality of switches configured to control the supply of power to the plurality of circuit blocks.

According to example embodiments of the inventive concepts, the external control signal includes a plurality of external switch control signals configured to control each of the plurality of switches.

According to example embodiments of the inventive concepts, the chip test system further includes a floating prevention controller configured to prevent leakage current caused by an input pin.

According to example embodiments of the inventive concepts, the floating prevention controller includes a flip flop configured to receive a data signal, and a multiplexer connected to the input pin and the flip flop, and configured to provide the data signal to a core of the chip to prevent the leakage current.

According to example embodiments of the inventive concepts, the input pin includes an input/output pin set to have an input function.

According to example embodiments of the inventive concepts, a chip includes a plurality of circuit blocks, a power switch unit configured to supply power to the plurality of circuit blocks, and a power switch controller configured to control the power switch unit in response to an external control signal such that the power switch controller is configured to selectively control supply of power to at least one circuit block of the plurality of circuit blocks based on the external control signal.

According to example embodiments of the inventive concepts, the chip further includes a chip controller configured to output an external mode signal and an internal control signal. The power switch controller is further configured to receive the internal control signal and the external mode signal, and configured to output a switch control signal to selectively control supply of power to the power switch unit based on the internal control signal and the external mode signal.

According to example embodiments of the inventive concepts, the switch control signal includes a plurality of internal switch control signals, the plurality of internal switch control signals corresponding to the plurality of circuit blocks.

According to example embodiments of the inventive concepts, the external control signal includes a plurality of external switch control signals and the internal control signal includes a plurality of internal switch control signals. The power switch controller is configured to output at least one of the external control signal and the internal control signal as the switch control signal.

According to example embodiments of the inventive concepts, the power switch controller includes a plurality of switches corresponding to the plurality of internal switch control signals, the plurality of switches configured to selectively output the plurality of external switch control signals and the plurality of internal switch control signals in response to the external mode signal.

According to example embodiments of the inventive concepts, the power switch controller is further configured to receive an external input/output control signal and an internal input/output control signal, the internal input/output control signal being supplied by the chip controller, and the power switch controller is configured to selectively output the external input/output control signal and the internal input/output control signal as an input/output control signal in response to the external mode signal.

According to example embodiments of the inventive concepts, the chip further includes a floating prevention controller configured to prevent leakage current to flow in the chip based on the input/output control signal.

### BRIEF DESCRIPTION OF THE DRAWINGS

The above and other features and advantages will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a view illustrating a chip test system according to an example embodiment of the inventive concepts;

FIG. 2 is a detailed view of FIG. 1;

FIG. 3 is a view of the chip of FIG. 1;

FIG. 4 is a detailed view of the power switch controller of FIG. 3;

FIG. 5 is a detailed view of the power switch unit of FIG. 3;

FIG. 6 is a view of a chip according to another example embodiment of the inventive concepts;

FIG. 7 is a detailed view of the power switch controller of FIG. 6; and

FIG. 8 is a detailed view of the floating prevention controller of FIG. 6.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

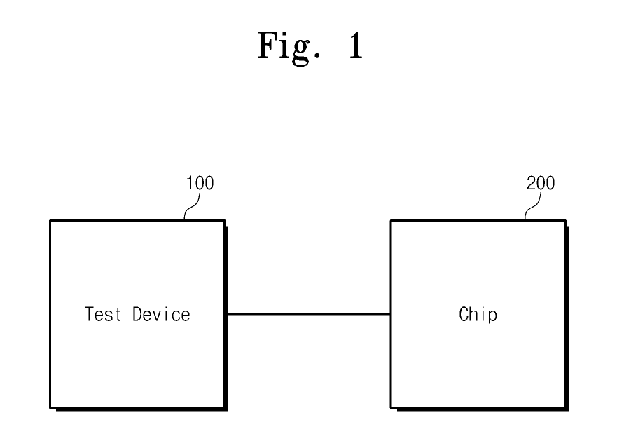

FIG. 1 is a view illustrating a chip test system according to example embodiments of the inventive concepts.

Referring to FIG. 1, the chip test system includes a test device 100, and a chip 200. The test device 100 tests functions of the chip 200. Testing of the functions of the chip 200 determines whether the chip 200 is defective or not before it is used.

Additionally, the chip 200 may be divided into a plurality of circuit blocks for operations of a device that uses the chip 200. These circuit blocks may include, for example, an analog to digital converter (ADC) circuit block, a digital signal processor (DSP) circuit block, an audio circuit block, a video circuit block, a modem circuit block, a peripheral component interconnect (PCI) circuit block, a memory circuit block, and a micro processor circuit block.

The test device 100 may test a standby current of the chip 200. As an example, the testing of the standby current may be used to calculate an expected battery usage time when the chip 200 is used in a product.

During a standby current test operation, power supplied to each circuit block in the chip 200 needs to be selectively cut off.

For this, the test device 100 provides a test pattern for performing a standby current test operation on the chip 200. The chip 200 receiving the test pattern may generate a control signal for power cut off therein so as to cut off power supplied to each circuit block. However, according to example embodiments of the inventive concepts, in a standby current test, the chip 200 selectively cuts off power supplied to a plurality of circuit blocks by using an externally provided control signal. Therefore, the chip 200, according to example embodiments of the inventive concepts, may operate according an external direct control from, for example, the test device 100, in a standby current test.

Hereinafter, a case wherein the test device 100 directly tests a standby current of the chip 200 will be described. However, another current besides the standby current of the chip 200 may be tested.

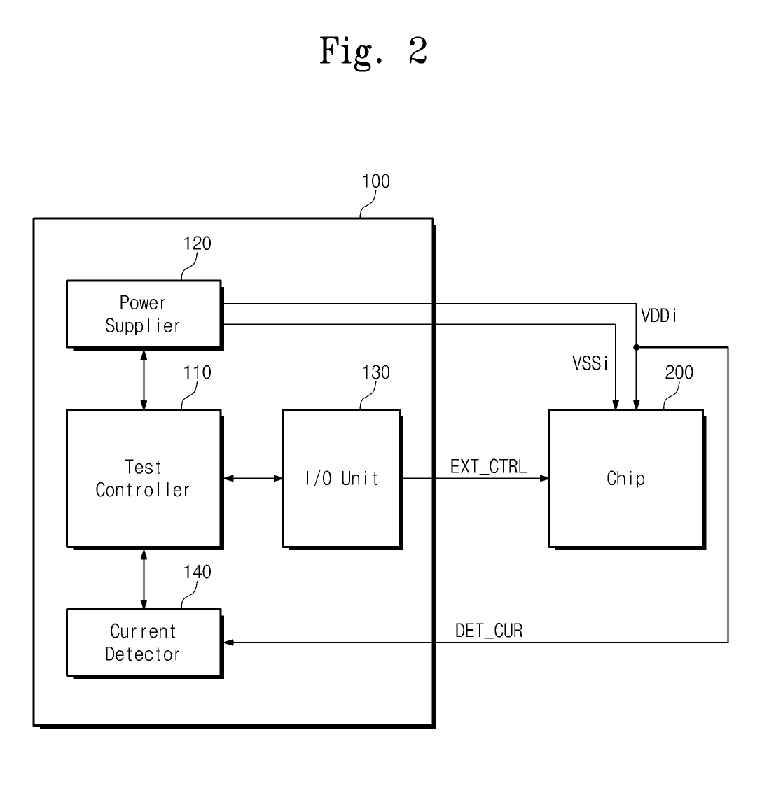

FIG. 2 is a detailed view of FIG. 1.

Referring to FIG. 2, the test device 100 includes a test controller 110, a power supplier 120, an input/output unit 130, and a current detector 140.

The test controller 110 controls general operations of the test device 100.

The power supplier 120 supplies power for a chip operation. A voltage supplied from the power supplier 120 is used for an operation of each circuit block in the chip 200.

The input/output unit 130 interfaces with the chip 200 in order for a test operation. For this, the input/output unit 130 may include a prober. Additionally, the input/output unit 130 may interface with a user to operate the test device 100.

The current detector 140 may measure a standby current of the chip 200 under a control of the test controller 110. As an example, the current detector 140 may measure a standby current of the chip 200 in response to a change of a power voltage VDDi provided to the chip 200.

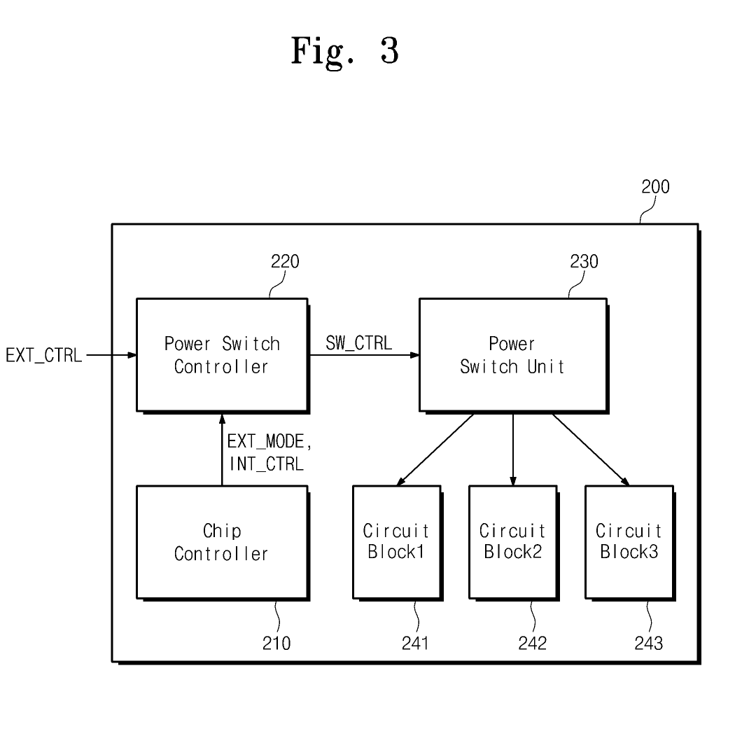

The test device 100 operates the chip 200 in an external control mode. The test controller 110 controls an operation for supplying a power to each circuit block in the chip 200 in the external control mode. The test controller 110 provides an external control signal EXT_CTRL to the chip 200 in the external control mode. Here, the external control signal EXT_CTRL is a control signal for selectively cutting off power supplied to each circuit block in the chip 200. FIG. 3 is a view of the chip of FIG. 1.

Referring to FIG. 3, the chip 200 includes a chip controller 210, a power switch controller 220, a power switch unit 230, and a plurality of circuit blocks 241, 242, and 243.

The chip controller 210 controls general operations of the chip 200. The chip controller 210 may operate in an external control mode. The chip controller 210 may operate in the external control mode when a signal for an operation of the external control mode is received from the test device 100. Herein, the chip controller 210 may operate in response to a signal externally provided to the chip 200. For this, the chip controller 210 generates an activated external mode signal EXT_MODE.

The power switch controller 220 supplies power to the plurality of circuit blocks 241, 242, and 243 according to a control of the power switch unit 230. If the power switch controller 220 receives the activated external mode signal EXT_MODE, the external control signal EXT_CTRL that is externally provided is supplied to the power switch unit 230 as a switch control signal SW_CTRL.

The power switch unit 230 supplies power to the plurality of circuit blocks 241, 242, and 243. Each of the plurality of circuit blocks 241, 242, and 243 is operated by the supplied power. The plurality of circuit blocks 241, 242, and 243 may include, for example, an ADC circuit block, a DSP circuit block, an audio circuit block, a video circuit block, a modem circuit block, a PCI circuit block, a memory circuit block, a micro processor circuit block or the like. Each of the plurality of circuit blocks 241, 242, and 243 may have various functions depending on a chip application field. Additionally, the chip controller 210 may operate in an internal control mode. The chip controller 240 may operate in the internal control mode if a control signal for an operation thereof is received from the test device 100. Herein, the chip controller 210 operates by a signal internally provided by the chip 200, for example, an internal control signal INT_CTRL. In this case, the chip controller 210 generates a deactivated external mode signal EXT_MODE.

The power switch controller 220 internally outputs the internal control signal INT_CTRL to the power switch unit 230 after receiving the deactivated external mode signal EXT_MODE.

The power switch unit 230 provides power to each of the plurality of circuit blocks 241, 242, and 243. The power switch unit 230 selectively cuts off and/or supplies power to each of the plurality of circuit blocks 241, 242, and 243 in response to deactivation of the external control signal EXT_CTRL received from the power switch controller 220.

Here, the external control signal EXT_CTRL and the internal control signal INT_CTRL are signals for supplying power to at least one selected circuit block to measure power consumption in a standby state and cutting off power to the remaining unselected circuit blocks.

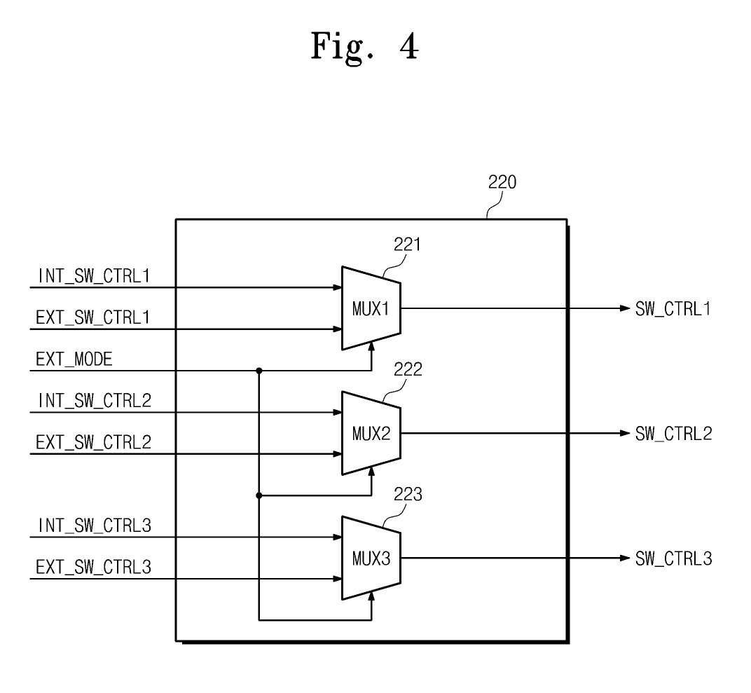

FIG. 4 is a detailed view of the power switch controller of FIG. 3.

Referring to FIG. 4, the power switch controller 220 includes a first multiplexer 221, a second multiplexer 222, and a third multiplexer 223.

The power switch controller 220 may operate in response to an external control signal EXT_CTRL.

The external control signal EXT_CTRL includes a first external switch control signal EXT_SW CTRL1, a second external switch control signal EXT_SW CTRL2, and a third external switch control signal EXT_SW CTRL3.

The power switch controller 220 may operate in an external control mode according to activation of the external mode signal EXT_MODE. The external mode signal EXT_MODE may be activated by the chip controller 210.

In addition, the power switch controller 220 may operate in response to the internal control signal INT_CTRL. The internal control signal INT_CTRL includes a first internal switch control signal INT_SW_CTRL1, a second internal switch control signal INT_SW_CTRL2, and a third internal switch control signal INT_SW_CTRL3. The first multiplexer 221 to the third multiplexer 223 select one of an external control signal EXT_CTRL and an internal control signal INT_CTRL in response to the external mode signal EXT_MODE.

If the external mode signal EXT_MODE is activated, the first multiplexer 221 selects the first external switch control signal EXT_SW_CTRL1. If the external mode signal EXT_MODE is deactivated, the first multiplexer 221 selects the first internal switch control signal INT_SW_CTRL1.

The first multiplexer 221 provides a selected signal (hereinafter, referred to as a first switch control signal SW_CTRL1) to the power switch unit 230. Here, the first switch control signal SW_CTRL1 is a signal for setting supply or cut off of power supplied to the first circuit block 241.

If the external mode signal EXT_MODE is activated, the second multiplexer 222 selects the second external switch control signal EXT_SW_CTRL2. If the external mode signal EXT_MODE is deactivated, the second multiplexer 222 selects the second internal switch control signal INT_SW_CTRL2.

The second multiplexer 222 provides a signal (hereinafter, referred to as a second switch control signal SW_CTRL2) selected by the external mode signal EXT_MODE to the power switch unit 230. Here, the second switch control signal SW_CTRL2 is a signal for setting supply or cut off of power supplied to the second circuit block 242.

In addition, if the external mode signal EXT_MODE is activated, the third multiplexer 223 selects the third external switch control signal EXT_SW_CTRL3. Additionally, if the external mode signal EXT_MODE is deactivated, the third multiplexer 223 selects the third internal switch control signal INT_SW_CTRL3.

The third multiplexer 223 provides a signal (hereinafter, referred to as a third switch control signal SW_CTRL3) selected by the external mode signal EXT_MODE to the power switch unit 230. Here, the third switch control signal SW_CTRL3 is a signal for setting supply or cut off of power supplied to the third circuit block 243.

Here, the power switch controller 220 of the chip 200 including three circuit blocks is illustrated as an example, and a number of circuit blocks and the corresponding number of multiplexers can be greater than or less than three.

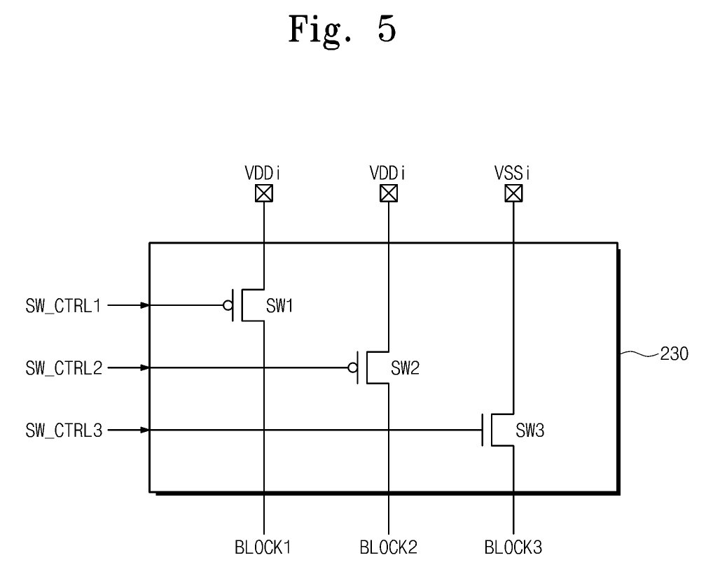

FIG. 5 is a detailed view of the power switch unit of FIG. 3.

Referring to FIG. 5, the power switch unit 230 includes a first switch SW1, a second switch SW2, and a third switch SW3.

The power switch unit 230 supplies power to each of the plurality of circuit blocks 241, 242, and 243. Herein, power may be supplied from a test device. Power supplied to the plurality of circuit blocks 241, 242, and 243 includes a power voltage VDDi and a ground voltage VSSi. The power switch unit 230 may selectively cut off power being supplied to the circuit blocks 241, 242, and 243 according to an external control during the external mode.

The first switch SW1 switches the power voltage VDDi to the first circuit block 241 in response to a first switch control signal SW_CTRL1. The first switch SW1 may be realized with an NMOS transistor.

The second switch SW2 switches the power voltage VDDi to the second circuit block 242 in response to a second switch control signal SW_CTRL2. The second switch SW2 may be realized with an NMOS transistor.

The third switch SW3 switches the ground voltage VSSi to the third circuit block 243 in response to a third switch control signal SW_CTRL3. The third switch SW3 may be realized with a PMOS transistor.

The number of switches may not be limited to three and can vary according to the number of circuit blocks included in the chip 200.

The power switch unit 230 controls each operation of the circuit blocks 241, 242, and 243 in the chip 200 by selectively supplying power voltage or ground voltage, which is supplied to each circuit block to measure standby current.

The first switch control signal SW_CTRL1 to the third switch control signal SW_CTRL3 selected by the external control signal EXT_CTRL may allow a power supplying operation for measuring standby current to be directly controlled from the external of the chip 200.

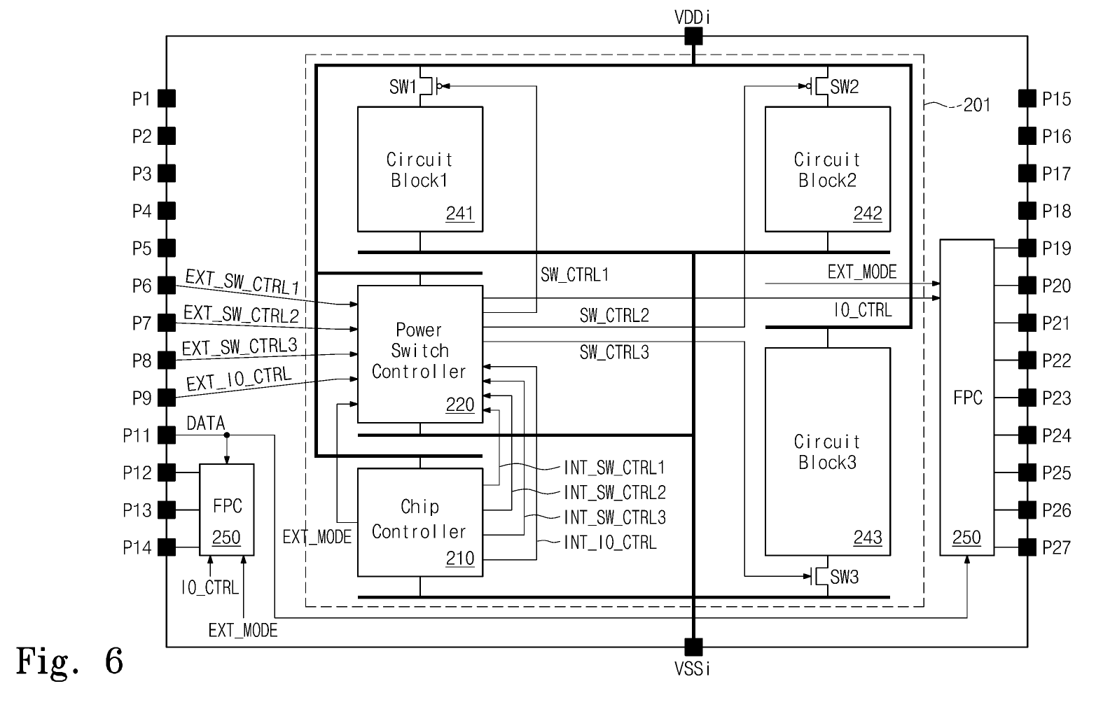

FIG. 6 is a view of a chip according to another example embodiment of the inventive concepts.

Referring to FIG. 6, the chip 200 includes a chip controller 210, a power switch controller 220, a plurality of circuit blocks 241, 242, and 243, and a floating prevention controller (FPC) 250. In addition, a core 201 includes the elements in the chip 200 (such as the chip controller 210, the power switch controller 220, and the plurality of circuit blocks 241, 242, and 243), excluding the floating prevention controller 250.

Firstly, an example embodiment case wherein the chip 200 operates in response to an external control signal of the inventive concepts will be described.

The chip controller 210 may control operations of the chip 200 in response to the external control signal EXT_CTRL. If the chip controller 210 is set/programmed in an external control mode, it activates an external mode signal EXT_MODE. The chip controller 210 may control internal operations of the chip in response to an externally provided signal. If a standby current test operation is performed, the chip controller 210 controls an operation of the chip 200 using a signal externally received by the chip. The chip controller 210 outputs an activated external mode signal EXT_MODE to the power switch controller 220.

The power switch controller 220 provides the externally provided external control signal EXT_CTRL to the power switch unit in the external control mode. The power switch controller 220 receives the external control signal EXT_CTRL. The external control signal EXT_CTRL is an external signal received from, for example, the test device 100. The external control signal EXT_CTRL is a control signal for selectively cutting off power supplied to each of the circuit blocks 241, 242, and 243. The external control signal EXT_CTRL includes a first external switch control signal EXT_SW CTRL1, a second external switch control signal EXT_SW CTRL2, and a third external switch control signal EXT_SW CTRL3.

The power switch controller 220 receives the activated external mode signal EXT_MODE. The power switch controller 220 selects the first external switch control signal EXT_SW_CTRL1 as a first switch control signal SW_CTRL1. The power switch controller 220 selects the second external switch control signal EXT_SW_CTRL2 as a second switch control signal SW_CTRL2. The power switch controller 220 selects the third external switch control signal EXT_SW_CTRL3 as a third switch control signal SW_CTRL3.

The power switch unit 230 supplies power to each of the plurality of circuit blocks 241, 242, and 243. The power switch unit 230 includes a first power switch SW1 to a third power switch SW3. The first power switch SW1 and the second power switch SW2 may be an NMOS transistor. The third power switch SW3 may be a PMOS transistor. As an example, the first power switch SW 1 to the third switch SW3 may correspond to switches SW1, SW2 and SW3 of the power switch unit 230 of FIG. 5.

The first power switch SW 1 is connected to and supplies a power voltage VDDi to the first circuit block 241. The first power switch SW1 may cut off power supplied to the first circuit block 241 in response to a first switch control signal SW_CTRL 1.

The second power switch SW2 is connected to and supplies a power voltage VDDi to the second circuit block 242. The second power switch SW2 may cut off power supplied to the second circuit block 242 in response to a second switch control signal SW_CTRL2.

The third power switch SW3 is connected to and supplies a ground voltage VSSi to the third circuit block 243. The third power switch SW3 may cut off power supplied to the third circuit block 243 in response to a third switch control signal SW_CTRL3.

Additionally, ground voltage is supplied to the first circuit block 241 and the second circuit block 242 and power voltage is supplied to the third circuit block 243. Accordingly, if each of the first power switch SW1 to the third power switch SW3 cuts off power, circuit blocks corresponding to the power switch no longer operates. For example, if a standby current of the first circuit block 241 is measured during a standby current test, the power switch controller 220 may receive an activated first external control signal EXT_SW_CTRL1 and may receive deactivated second and third external control signals EXT_SW_CTRL2 and EXT_SW_CTRL3. If the external mode signal EXT_MODE is activated by the chip control unit 210, the first external control signal to the third external control signal EXT_SW_CTRL1 to EXT_SW_CTRL3 may be selected as the first switch control signal SW_CTRL1 to the third switch control signal SW_CTRL3.

The first power switch SW1 is turned on in response to the first switch control signal SW_CTRL1, and the second power switch SW2 and the third power switch SW3 are turned off in response to the second switch control signal SW_CTRL2 and the third switch control signal SW_CTRL3, respectively. That is, power is supplied to the first circuit block 241 and power is cut off to the second circuit block 242 and the third circuit block 243.

At this point, if power supplied from the test device 100 to the chip 200 is used for standby current, a standby current of the first circuit block 241 may be measured.

In the same manner, the test device 100 may selectively perform an operation for supplying external power to the inner circuit blocks of the chip 200 to measure standby current. The test device 100 may measure a standby current of at least one of the first to third circuit blocks 241 to 243.

An operation of the chip 200 using an internal control signal will be described below.

If the chip controller 210 is set/programmed in an internal control mode, it deactivates the external mode signal EXT_MODE. The chip controller 210 outputs a deactivated external mode signal EXT_MODE to the power switch controller 220.

The power switch controller 220 receives an internal control signal INT_CTRL. The internal control signal INT_CTRL is an internal signal received from, for example, the chip controller 210. The internal control signal INT_CTRL is a control signal for selectively cutting off power supplied to each of the circuit blocks 241, 242, and 243. The internal control signal INT_CTRL includes a first internal switch control signal INT_SW_CTRL1, a second internal switch control signal INT_SW_CTRL2, and a third internal switch control signal INT_SW_CTRL3.

The power switch controller 220 receives a deactivated external mode signal EXT_MODE. The power switch controller 220 selects the first internal switch control signal INT_SW_CTRL1 as a first switch control signal SW_CTRL1. The power switch controller 220 selects the second internal switch control signal INT_SW_CTRL2 as a second switch control signal SW_CTRL2. The power switch controller 220 selects the third internal switch control signal INT_SW_CTRL2 as a third switch control signal SW_CTRL3.

The next operation is similar to the external control mode and its detailed description will be omitted for the sake of brevity.

In addition, the chip 200 includes a plurality of pins P1 to P27 for input/output of a signal. The plurality of pins P1 to P27 are input terminals and output terminals. Moreover, the plurality of pins P1 to P27 may be pads.

The floating prevention controller 250 reduces leakage current caused by an input pin during a standby current test. The floating prevention controller 250 may prevent leakage current occurrence due to an inverter operation connected to an input pin, by providing data to an inner circuit connected to an input pin.

The sixth pin P6 to the ninth pin P9 and the eleventh pin P11 are control pins where the external control signal EXT_CTRL is inputted. The sixth pin P6 to eighth pin P8 receive control signals such as EXT_SW_CTRL1, EXT_SW_CTRL2, and EXT_SW_CTRL3. The ninth pin P9 receives an external input/output control signal EXT_IO_CTRL for controlling input/output pins. The eleventh pin P11 receives a data signal DATA to be provided to the floating prevention controller 250.

The floating prevention controller 250 is connected to the twelfth pin P12 to the fourteenth pin P14 and the nineteenth P19 to the twenty seventh P27. In addition, the floating prevention controller 250 is not connected to the first pin P1 to the fifth pin P5 and the fifteenth pin P15 to eighteenth pin P18.

Accordingly, the pins P12 to P14 and P19 to P27 to which the floating prevention controller 250 are connected are input pins having an input function, and the pins P1 to P5 and P15 to P18 to which the floating prevention controller 250 are not connected are output pins.

Moreover, pins in the chip 200 may be classified into three types. The pins may be divided into an input pin PI with only an input function, an output pin PO with only an output function, and an input/output pin PIO with a selective input/output function.

The floating prevention controller 250 receives an external data signal DATA. The floating prevention controller 250 receives an external mode signal EXT_MODE from the chip controller 210 and receives an input/output control signal IO_CTRL from the power switch controller 220.

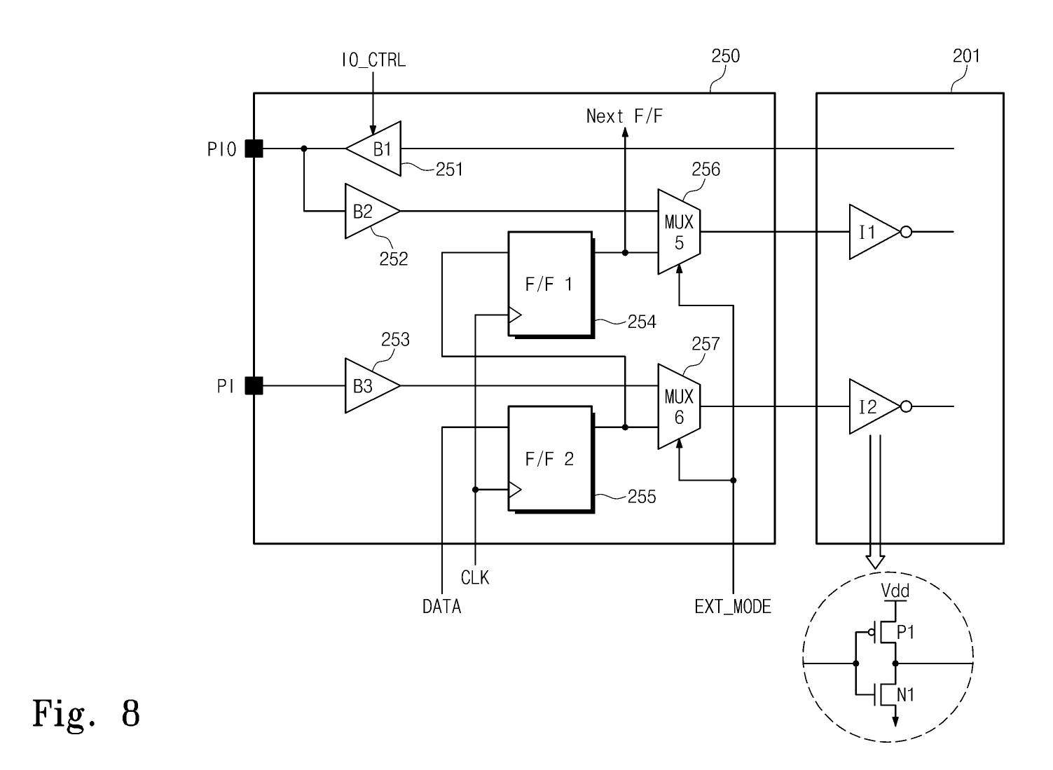

A configuration of the floating prevention controller 250 will be described in more detail with reference to FIG. 8.

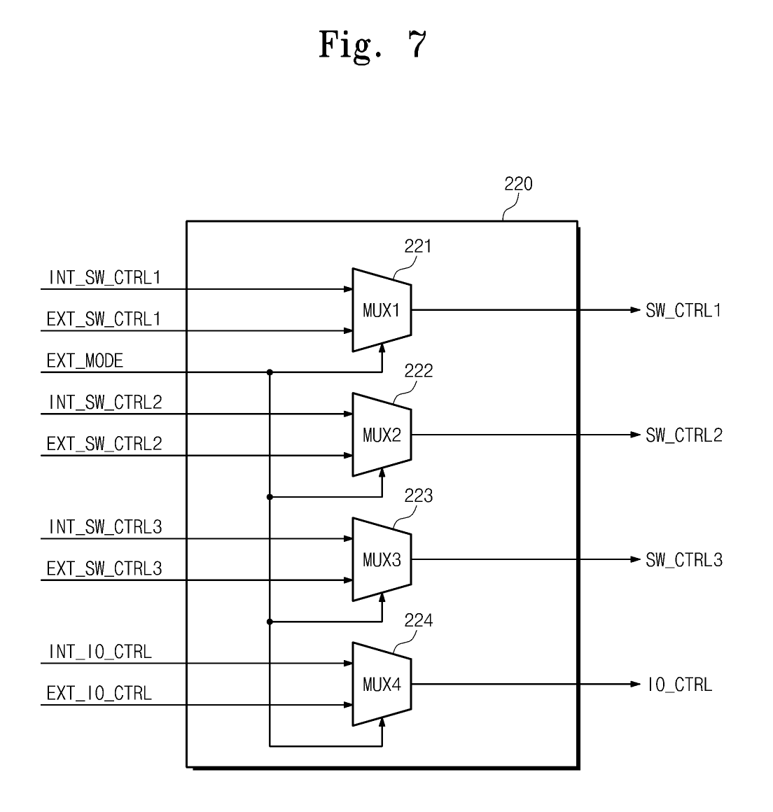

FIG. 7 is a detailed view of the power switch controller of FIG. 6.

Referring to FIG. 7, the power switch controller 220 includes a first multiplexer 221, a second multiplexer 22, a third multiplexer 223, and a fourth multiplexer 224.

The first multiplexer 221 to the third multiplexer 223 receive an internal control signal INT_CTRL and an external control signal EXT_CTRL, respectively, in order to measure standby current. Operations of the first multiplexer 221 to the third multiplexer 223 may be similar to the operation of the power switch controller 220 of FIG. 4.

The power switch controller 220 of FIG. 7 may additionally include a fourth multiplexer 224 generating an input/output control signal IO_CTRL of pins having an input/output function.

The fourth multiplexer 224 selects an external input/output control signal EXT_IO_CTRL when the external mode signal EXT_MODE is activated. The fourth multiplexer 224 selects an internal input/output control signal INT_IO_CTRL when the external mode signal EXT_MODE is deactivated.

The fourth multiplexer 224 provides a signal (referred to as an input/output control signal IO_CTRL) selected in response to the external mode signal EXT_MODE to the floating prevention controller 250. Here, the input/output control signal IO_CTRL is a signal setting a function (or, an operation) of an input/output pin PIO. The input/output control signal IO_CTRL may be configured to allow an input/output pin PIO connected to the floating prevention controller 250 to have an input function or may be configured to allow an input/output pin PIO not connected to the floating prevention controller 250 to have an output function.

FIG. 8 is a detailed view of the floating prevention controller of FIG. 6.

Referring to FIG. 8, the floating prevention controller 250 includes a first buffer 251, a second buffer 252, a third buffer 253, a first flip flop 254, a second flip flop 255, a fifth multiplexer 256, and a sixth multiplexer 257.

The first buffer 251 outputs a signal provided from the core 201 through the input/output pin PIO. The first buffer 251 receives an input/output control signal IO_CTRL and deactivates an operation of the first buffer 251 according to activation of the input/output control signal IO_CTRL, thereby setting the input/output pin PIO to operate as an input pin.

Additionally, the input/output control signal IO_CTRL may set the input/output pin PIO to operate as an output pin by activating an operation of the first buffer B1. At this point, the input/output pin PIO is not connected to the floating prevention controller 250.

The second buffer 252 outputs an external signal of the chip 200 received through the input/output pin PIO to the fifth multiplexer 256.

The third buffer 253 outputs an external signal received through the input pin PI to the sixth multiplexer 257.

The second flip flop 255 receives a clock signal CLK. The clock signal CLK may be provided from the chip controller 210. The second flip flop 255 outputs the received data signal DATA to the sixth multiplexer 257.

The sixth multiplexer 257 receives an external mode signal EXT_MODE. The sixth multiplexer 257 outputs an output signal of the third buffer 253 when the external mode signal EXT_MODE is deactivated. Additionally, the sixth multiplexer 257 outputs a data signal DATA of the second flip flop 255 to a second inverter I2 of the core 201 when the external mode signal EXT_MODE is activated.

The first flip flop 254 receives the clock signal CLK. The clock signal CLK may be provided from the chip controller 210. The first flip flop 254 receives a data signal DATA output from the second flip flop 255 and outputs the received data signal DATA to the fifth multiplexer 256.

In addition, the data signal output from the first flip flop 254 is provided to the next flip flop (not shown).

The fifth multiplexer 256 receives an external mode signal EXT_MODE. The fifth multiplexer 256 outputs an output signal of the second buffer 252 when the external mode signal EXT_MODE is deactivated. The fifth multiplexer 256 outputs a data signal DATA of the first flip flop 254 to the first inverter I1 when the external mode signal EXT_MODE is activated.

As an example, pins other than pins for receiving an external control signal EXT_CTRL (such as a first external switch control signal EXT_SW_CTRL1, a second external switch control signal EXT_SW_CTRL2, a third external switch control signal EXT_SW_CTRL3, an external input/output control signal EXT_IO_CTRL, and a data signal DATA) do not receive a signal.

Accordingly, if a data signal determined as ‘1’ or ‘0’ is not received in the inverters I1 and I2 of the core 201 corresponding to an input pin PI and an input/output pin PIO selected to have an input function, leakage current occurs.

As an example, the inverter I2 includes a PMOS transistor P1 and an NMOS transistor N1 connected in series between power voltage Vdd and ground. An input signal of the inverter is input to each of gates of the PMOS transistor P1 and the NMOS transistor N1. Moreover, an inverted input signal is output through a contact point of the MOS transistor P1 and the NMOS transistor N1.

Therefore, if there is a signal that cannot turn on the PMOS transistor P1 and the NMOS transistor N2 as ‘1’ and ‘0’, leakage current occurs in the inverter.

This leakage current may serve as an error factor during a standby current test. That is, accurate standby current may not be measured. Accordingly, floating due to leakage current is prevented by providing the floating prevention controller 250 (outputting predetermined data to a corresponding inverter) with respect to an input pin PI and an input/output pin PIO selected to have an input function.

Moreover, since an output pin PO and an input/output pin PIO selected to have an output function output an internal signal to the outside of the chip 200, leakage current does not occur. Accordingly, an output pin PO and an input/output pin PIO selected to have an output function do not require the floating prevention controller 250.

Therefore, if the floating prevention controller 250 according to example embodiments of the inventive concepts is additionally included, accurate standby current is measured by reducing errors of a standby current test.

Also, if the chip 200 according to example embodiments the inventive concepts is used, direct external control of the chip 200 is possible through its pin during a current measuring operation.

According to example embodiments of the inventive concepts, using a chip structure directly controlled by an external control signal, standby current is measured by a direct external control of the chip during a standby current measurement.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A chip, comprising:
a plurality of circuit blocks;
a power switch unit configured to supply power to the plurality of circuit blocks; and
a power switch controller configured to control the power switch unit in response to an external control signal, the external control signal selectively controlling supply of power to at least one circuit block of the plurality of circuit blocks.

2. The chip of claim 1, wherein the power switch unit controls the supply of power to each of the plurality of circuit blocks and includes a plurality of switches configured to control the supply of power to the plurality of circuit blocks.

3. The chip of claim 2, wherein the external control signal includes a plurality of external switch control signals configured to control each of the plurality of switches.

4. The chip of claim 1, further comprising a floating prevention controller configured to prevent leakage current caused by an input pin.

5. The chip of claim 4, wherein the floating prevention controller comprises:
a flip flop configured to receive a data signal; and
a multiplexer connected to the input pin and the flip flop, and configured to provide the data signal to a core of the chip to prevent the leakage current.

6. The chip of claim 5, wherein the input pin comprises an input/output pin set to have an input function.

7. A chip test system, comprising:
a test device; and
a chip tested by the test device, wherein the chip includes,
a plurality of circuit blocks;
a power switch unit configured to supply power to the plurality of circuit blocks; and
a power switch controller configured to control the power switch unit in response to an external control signal, the external control signal selectively controlling supply of power to at least one circuit block of the plurality of circuit blocks.

8. The chip test system of claim 7, wherein the test device comprises:
a power supply unit configured to supply power to the chip; and
a current measuring unit configured to measure a standby current flowing in the chip while supply of power to the plurality of circuit blocks in the chip is being controlled in response to the external control signal.

9. The chip test system of claim 8, wherein the current measuring unit measures the standby current using the supply of power to the chip.

10. The chip test system of claim 8, wherein the power switch unit controls the supply of power to each of the plurality of circuit blocks and includes a plurality of switches configured to control the supply of power to the plurality of circuit blocks.

11. The chip test system of claim 10, wherein the external control signal includes a plurality of external switch control signals configured to control each of the plurality of switches.

12. The chip test system of claim 7, further comprising:
a floating prevention controller configured to prevent leakage current caused by an input pin.

13. The chip test system of claim 12, wherein the floating prevention controller comprises:
a flip flop configured to receive a data signal; and
a multiplexer connected to the input pin and the flip flop, and configured to provide the data signal to a core of the chip to prevent the leakage current.

14. A chip, comprising:
a plurality of circuit blocks;
a power switch unit configured to supply power to the plurality of circuit blocks; and
a power switch controller configured to control the power switch unit in response to an external control signal such that the power switch controller is configured to selectively control supply of power to at least one circuit block of the plurality of circuit blocks based on the external control signal.

15. The chip of claim 14, further comprises:
a chip controller configured to output an external mode signal and an internal control signal, wherein
the power switch controller is further configured to receive the internal control signal and the external mode signal, and configured to output a switch control signal to selectively control supply of power to the power switch unit based on the internal control signal and the external mode signal.

16. The chip of claim 15, wherein the switch control signal includes a plurality of internal switch control signals, the plurality of internal switch control signals corresponding to the plurality of circuit blocks.

17. The chip of claim 16, wherein
the external control signal includes a plurality of external switch control signals and the internal control signal includes a plurality of internal switch control signals, and
the power switch controller is configured to output at least one of the external control signal and the internal control signal as the switch control signal.

18. The chip of claim 17, wherein
the power switch controller includes a plurality of switches corresponding to the plurality of internal switch control signals, the plurality of switches configured to selectively output the plurality of external switch control signals and the plurality of internal switch control signals in response to the external mode signal.

19. The chip of claim 15, wherein the power switch controller is further configured to receive an external input/output control signal and an internal input/output control signal, the internal input/output control signal being supplied by the chip controller, and
the power switch controller is configured to selectively output the external input/output control signal and the internal input/output control signal as an input/output control signal in response to the external mode signal.

20. The chip of claim 19, further comprising:
a floating prevention controller configured to prevent leakage current to flow in the chip based on the input/output control signal.
